(19) United States
(12) Patent Application Publication
(10) Pub. No.: US 2026/0101516 A1
(43) Pub. Date: Apr. 9, 2026

(54) SEMICONDUCTOR DEVICE AND METHOD OF FABRICATING THE SAME

(71) Applicant: Samsung Electronics Co., Ltd., Suwon-si (KR)

(72) Inventors: Yumin KIM, Suwon-si (KR); Garam PARK, Suwon-si (KR); Hyunjae SONG, Suwon-si (KR); Minhyun LEE, Suwon-si (KR); Seung Dam HYUN, Suwon-si (KR)

(73) Assignee: Samsung Electronics Co., Ltd., Suwon-si (KR)

(21) Appl. No.: 19/345,597

(22) Filed: Sep. 30, 2025

(30) Foreign Application Priority Data
Oct. 7, 2024 (KR) 10-2024-0136040

(51) Int. Cl. H10B 63/00

(52) U.S. Cl. CPC H10B 63/845

(57) ABSTRACT

A semiconductor device may include a plurality of first electrodes stacked above a substrate in a first direction, a second electrode penetrating the plurality of first electrodes, and a variable resistance device layer surrounding the second electrode. A work function of a material in the plurality of first electrodes may be smaller than a work function of a material in the second electrode.

### CROSS-REFERENCE TO RELATED APPLICATIONS

This application claims the benefit of Korean Patent Application No. 10-2024-0136040, filed on Oct. 7, 2024 in the Korean Intellectual Property Office, the disclosure of which is incorporated herein by reference in its entirety.

### BACKGROUND

### 1. Field

The present disclosure relates to a semiconductor device and/or a method of fabricating the same.

### 2. Description of the Related Art

As a semiconductor device for storing a large volume of data may be required in an electronic system, research on methods for increasing data storage capacity of the semiconductor device is currently conducted. As one of the methods for increasing the data storage capacity of the semiconductor device, a semiconductor device including three-dimensionally arranged memory cells instead of two-dimensionally arranged memory cells is proposed.

### SUMMARY

An aspect of the present disclosure provides a semiconductor device with limited and/or suppressed occurrence of a sneak current and/or a method of fabricating the same.

Another aspect of the present disclosure also provides a more miniaturized semiconductor device with improved integration density and/or a method of fabricating the same.

However, aspects of example embodiments of the present disclosure are not limited to the aspects described above and other aspects may be clearly understood from the following example embodiments by those skilled in the art.

According to an example embodiment, a semiconductor device may include a plurality of first electrodes stacked above a substrate in a first direction, a second electrode configured to penetrate the plurality of first electrodes, and a variable resistance device layer surrounding the second electrode. A work function of a material in the plurality of first electrodes may be smaller than a work function of a material in the second electrode.

According to an example embodiment, a method of fabricating a semiconductor device may include alternately stacking a plurality of insulation films and a plurality of first electrodes in a first direction, forming a hole penetrating the plurality of insulation films and the plurality of first electrodes in the first direction, forming a variable resistance device layer on an inner side wall of the hole, and forming a second electrode in the hole to fill the hole. The second electrode may be on the variable resistance device layer.

According to an example embodiment, a semiconductor device may include a plurality of first electrodes stacked above a substrate in a first direction and including silicon doped with an impurity, a second electrode configured penetrating the plurality of first electrodes and extending in the first direction, and a single-film variable resistance device layer surrounding the second electrode and connected to the plurality of first electrodes. A work function of a material in the plurality of first electrodes may be smaller than a work function of a material in the second electrode.

Additional aspects of example embodiments will be set forth in part in the description which follows and, in part, will be apparent from the description.

According to example embodiments, it is possible to limit and/or suppress occurrence of a sneak current in a semiconductor device.

According to example embodiments, it is possible to improve integration density of the semiconductor package and reduce and/or minimize the semiconductor device.

### BRIEF DESCRIPTION OF THE FIGURES

These and/or other aspects, features, and advantages of inventive concepts will become apparent and more readily appreciated from the following description of example embodiments, taken in conjunction with the accompanying drawings of which:

FIG. 1 is a diagram for describing a semiconductor device according to some example embodiments of the present disclosure;

FIGS. 2 and 3 are diagrams for describing a semiconductor device according to some example embodiments of the present disclosure;

FIGS. 4 through 7 are diagrams for describing a method of fabricating a semiconductor device according to some example embodiments of the present disclosure;

FIG. 8 is a diagram for describing a semiconductor device according to some other example embodiments of the present disclosure; and

FIG. 9 is a schematic diagram of an electronic system including a semiconductor device according to some embodiments.

### DETAILED DESCRIPTION

Before example embodiments are described, terms or words used in the present disclosure and the accompanying claims are not to be limited to general definitions or dictionary definitions. The terms and words are to be construed under a principle that an inventor may appropriately define a concept of a term in order to describe inventive concepts in the best way. Thus, since example embodiments described in the present disclosure and configurations illustrated in the accompanying drawings are examples only and do not represent all of the technical spirit of the present disclosure, it should be understood that various equivalents and modifications that may replace the example embodiments and configurations may be present at the time of filing the application of the present disclosure.

In the following descriptions, terms such as “including” or “comprising” indicate that a feature, a number, an operation, an action, an element, a component, or a combination thereof is present. It should be understood that the terms “including” or “comprising” are not to exclude in advance a possibility that one or more other features, numbers, operations, actions, elements, components, or combinations thereof may be present or added.

In the following descriptions, terms in a singular form include terms in a plural form unless an apparently and contextually conflicting description is present. Terms including an ordinal number such as “first” or “second” used in the present specification may be used to describe various elements. However, the elements may not be limited by the terms including the ordinal number. The terms may be used to contextually distinguish one element from another element in a part of the specification. Within a range of the technical spirit of the present disclosure, a first element may be referred to as a second element in another part of the specification, and reversely, the second element may be referred to as the first element in another part of the specification. Also, in the accompanying drawings, shapes, sizes, or the like of elements in the drawings may be exaggerated for clearer description.

In addition, it should be noted in advance that an expression such as an upper side, an upper portion, a lower side, a lower portion, a side surface, a front surface, or a rear surface is based on directions illustrated in the drawings and that the expression may be changed when a direction of a corresponding object is changed. Shapes, sizes, or the like of elements in the drawings may be exaggerated for clearer description.

Hereinafter, example embodiments of the present disclosure will be described with reference to the drawings.

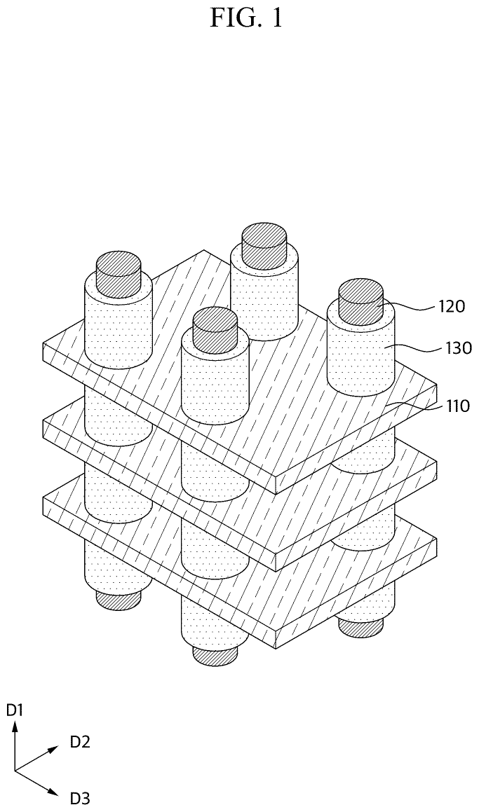

FIG. 1 is a diagram for describing a semiconductor device according to some example embodiments of the present disclosure.

Referring to FIG. 1, the semiconductor device according to some example embodiment may include a plurality of first electrodes 110, a second electrode 120, and a variable resistance device layer 130.

According to some example embodiments, the plurality of first electrodes 110 may be stacked in a first direction D1. The plurality of first electrodes 110 may be stacked so as to cross the second electrode 120. The plurality of first electrodes 110 may be spaced apart from each other in the first direction D1. An insulation film may be disposed between the plurality of first electrodes 110 that are spaced apart from each other. The plurality of first electrodes 110 may include a semiconductor material doped with an impurity and the semiconductor material may be doped with a high concentration of the impurity. For example, each of the plurality of first electrodes 110 may include silicon (Si).

According to some example embodiments, the semiconductor material included in the plurality of first electrodes 110 may include, for example, at least one of amorphous silicon and amorphous silicon-germanium. However, example embodiments are not limited thereto. The impurity included in the plurality of first electrodes 110 may include, as an example, at least one of phosphorus (P), arsenic (As), antimony (Sb), and bismuth (Bi). As another example, the impurity included in the plurality of first electrodes 110 may be one of boron (B) and gallium (Ga), but example embodiments are not limited thereto.

According to some example embodiments, the second electrode 120 may penetrate the plurality of first electrodes 110. The second electrode 120 may cross the plurality of first electrodes 110. The second electrode 120 may have a pillar shape. The second electrode 120 in the pillar shape may have a structure filled with a material of the second electrode 120, not a structure of which an inside is empty. The second electrode 120 may be extended in the first direction D1. The second electrode 120 may be extended in the first direction D1 across the plurality of first electrodes 110. The second electrode 120 may have a pillar shape continuously extended and not divided in the first direction D1. The second electrode 120 may protrude further than the variable resistance device layer 130 in the first direction D1. For example, an upper surface of the second electrode 120 may be disposed higher than an upper surface of the variable resistance device layer 130 in the first direction D1.

According to some example embodiments, the second electrode 120 may include at least one of a metal, a metal alloy, a conductive metallic nitride, a metallic silicide, a doped semiconductor material, a conductive metallic oxide, and a conductive metallic oxynitride. The second electrode 120 may include, for example, at least one of titanium nitride (TiN), a tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof, but example embodiments are not limited thereto. The conductive metallic oxide and the conductive metallic oxynitride may include a form in which the above-described substance is oxidized, but example embodiments are not limited thereto.

According to some example embodiments, the variable resistance device layer 130 may surround the second electrode 120. An inner side wall of the variable resistance device layer 130 may be in contact with the second electrode 120. The variable resistance device layer 130 may be disposed between the plurality of first electrodes 110 and the second electrode 120. The variable resistance device layer 130 may be extended in the first direction between the plurality of first electrodes 110 and the second electrode 120. The variable resistance device layer 130 may be a part of a body continuously extended and not divided in the first direction D1 to surround the second electrode 120. The variable resistance device layer 130 may be formed as a single film.

According to some example embodiments, the variable resistance device layer 130 may include, for example, silicon oxide, silicon nitride, silicon oxynitride, and a high-permittivity material having permittivity higher than that of silicon oxide. The high-permittivity material may include, for example, at least one of aluminum oxide, hafnium oxide, lanthanum oxide, tantalum oxide, titanium oxide, lanthanum hafnium oxide, lanthanum aluminum oxide, dysprosium scandium oxide and a combination thereof.

According to some example embodiments, the variable resistance device layer 130 may include a material of which resistance is changed depending on an electric field. The variable resistance device layer 130 may include a transition metal oxide. The variable resistance device layer 130 may include a phase-change material, a ferroelectric material, or a magnetic material. The variable resistance device layer 130 may include, for example, nickel oxide (NiO) or perovskite. The perovskite may include a compound such as manganite, a titanate, or a zirconate. The variable resistance device layer 130 may include two or more compounds selected from a group including tellurium (Te), selenium (Se), germanium (Ge), antimony (Sb), bismuth (Bi), lead (Pb), tin (Sn), silver (Ag), arsenic (As), sulfur (S), silicon (Si), phosphorus (P), oxygen (O), and carbon (C).

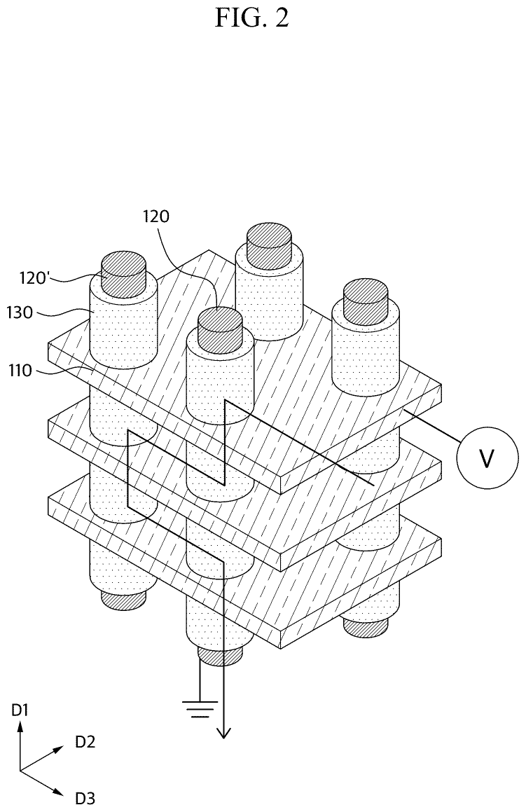

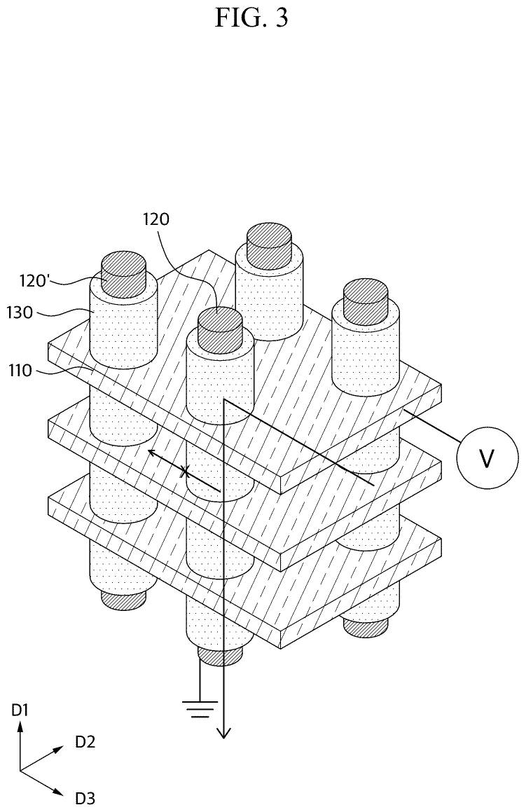

According to some example embodiments, a work function of a material included in the plurality of first electrodes 110 and a work function of a material included in the second electrode 120 may be different from each other. The work function of the material included in the plurality of first electrodes 110 may be smaller than the work function of the material included in the second electrode 120. The work function of the material included in the second electrode 120 may be larger than the work function of the material included in the plurality of first electrodes 110. Thus, movement of an electron from the second electrode 120 to the variable resistance device layer 130 may require more energy compared to the movement of the electron from the plurality of first electrodes 110 to the variable resistance device layer 130. FIGS. 2 and 3 will be referenced for a description therefor.

FIGS. 2 and 3 are diagrams for describing a semiconductor device according to some example embodiments of the present disclosure.

Referring to FIG. 2, for an operation of the semiconductor device, an operation voltage V may be provided to one of the plurality of first electrodes 110, and a ground voltage may be provided to the second electrode 120 which is selected. An electron may move from a first electrode 110 to the variable resistance device layer 130. When a work function of the second electrode 120 is lower than a work function of the plurality of first electrodes 110, a sneak current may occur because the electron may easily move from a second electrode 120′ to the variable resistance device layer 130.

Referring to FIG. 3, when the work function of the second electrode 120 is higher than the work function of the plurality of first electrodes 110, the electron may not move from the second electrode 120′ to the variable resistance device layer 130. Thus, in the semiconductor device according to some example embodiments, since a barrier to movement of the electron is formed through a difference between work functions of the plurality of first electrodes 110 and the second electrode 120, an electric current may flow, even without a selector, only between a first electrode 110 and the second electrode 120 which are connected to the variable resistance device layer 130 which is selected. The electric current may flow in one direction between the second electrode 120 and the plurality of first electrodes 110.

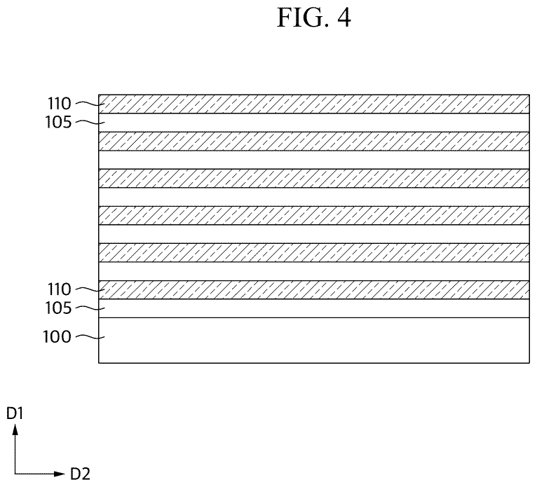

FIGS. 4 through 7 are diagrams for describing a method of fabricating a semiconductor device according to some example embodiments of the present disclosure.

Referring to FIG. 4, a plurality of insulation films 105 and the plurality of first electrodes 110 may be alternately stacked above a substrate 100. The plurality of insulation films 105 and the plurality of first electrodes 110 may be stacked in the first direction D1 above the substrate 100. The first direction D1 may be a direction crossing an upper surface or a lower surface of the substrate 100.

According to some example embodiments, each of the plurality of insulation films 105 may include an insulation material. For example, the plurality of insulation films 105 may include at least one of silicon oxide, silicon nitride, and silicon oxynitride, but example embodiments are not limited thereto. The plurality of first electrodes 110 may include silicon doped with high-concentration phosphorus (P).

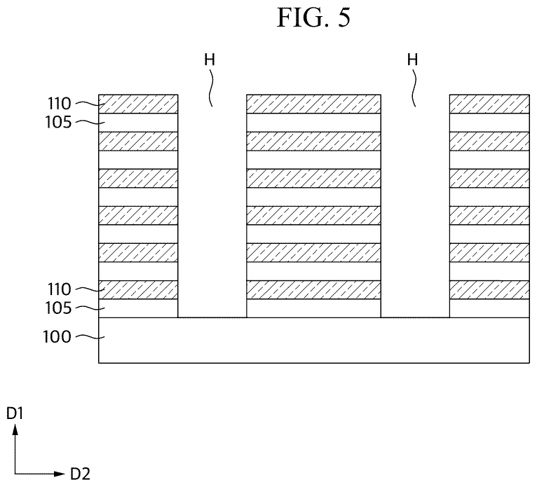

Referring to FIG. 5, a hole H penetrating the plurality of insulation films 105 and the plurality of first electrodes 110 may be formed. The hole H may penetrate the plurality of insulation films 105 and the plurality of first electrodes 110 in the first direction D1. The plurality of insulation films 105 and the plurality of first electrodes 110 may be exposed in the hole H. The hole H may expose the plurality of insulation films 105 and the plurality of first electrodes 110.

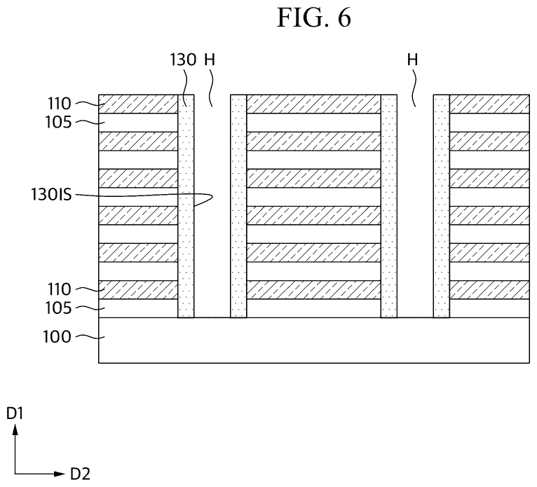

Referring to FIG. 6, the variable resistance device layer 130 may be formed in the hole H. The variable resistance device layer 130 may be extended along an inner side wall of the hole H. The variable resistance device layer 130 may cover the plurality of insulation films 105 and the plurality of first electrodes 110 in the hole H. The variable resistance device layer 130 may be connected to the plurality of insulation films 105 and the plurality of first electrodes 110 in the hole H. The variable resistance device layer 130 may be extended in the first direction D1.

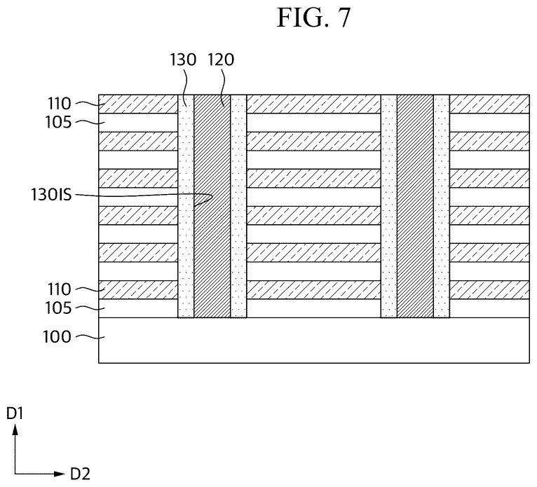

Referring to FIG. 7, the second electrode 120 may be formed on the variable resistance device layer 130. The second electrode 120 may fill the hole H (of FIG. 6). The second electrode 120 may be extended along an inner side wall 130IS of the variable resistance device layer 130. The second electrode 120 may cover the inner side wall 130IS of the variable resistance device layer 130.

In a method according to the related arts for forming a plurality of first electrodes including a conductive metal, a plurality of sacrificial films may be stacked and the plurality of sacrificial films may be been removed after a hole has been formed, and then the plurality of first electrodes of the conductive metal may be formed. According to example embodiments of the present disclosure, the plurality of first electrodes 110 may include a high-concentration impurity and may be stacked and formed without an additional sacrificial film. Thus, the method of fabricating the semiconductor device according to example embodiments of the present disclosure may be simpler than the method according to the related arts.

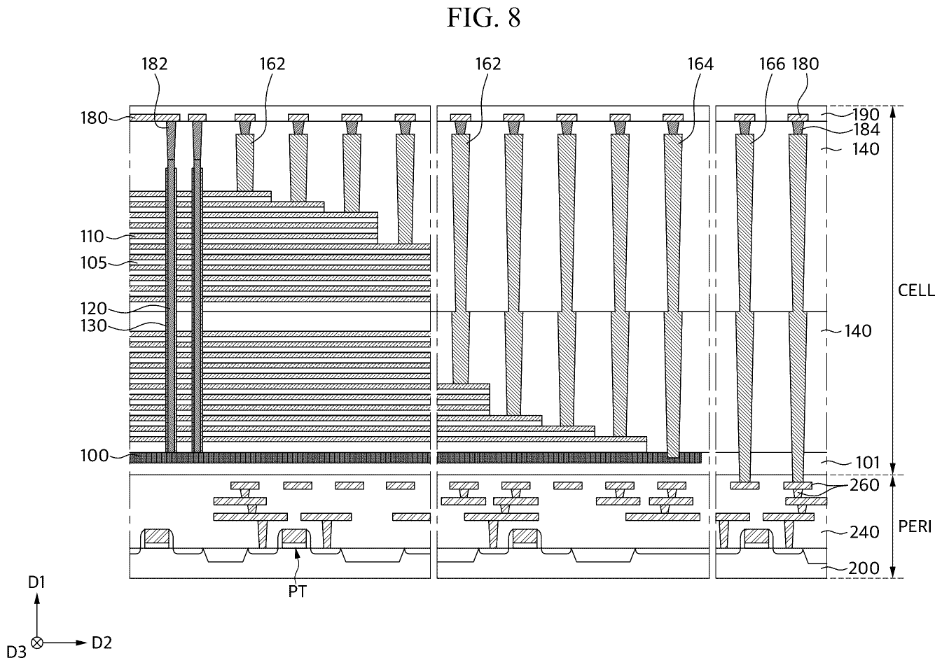

FIG. 8 is a diagram for describing a semiconductor device according to some other example embodiments of the present disclosure.

Referring to FIG. 8, the semiconductor device according to some other example embodiments may include a cell structure CELL and a peripheral circuit structure PERI.

According to some example embodiments, the cell structure CELL may include the substrate 100, an insulation substrate 101, the plurality of first electrodes 110, the second electrode 120, the variable resistance device layer 130, the plurality of insulation films 105, an inter-layer insulation film 140, a cell wiring line 180, and a gate contact 162.

According to some example embodiments, the substrate 100 may include, for example, a semiconductor substrate such as a silicon substrate, a germanium substrate, or a silicon-germanium substrate. Alternatively, the substrate 100 may include a silicon-on-insulator (SOI) substrate, a germanium-on-insulator (GOI) substrate, or the like.

According to some example embodiments, the substrate 100 may include an impurity. For example, the substrate 100 may include an n-type impurity (e.g., phosphorus (P), arsenic (As), or the like). However, example embodiments are not limited thereto. For example, the substrate 100 may also include a P-type impurity. The substrate 100 may include poly-silicon (poly-Si) doped with the N-type impurity.

According to some example embodiments, the insulation substrate 101 may be formed around the substrate 100. The insulation substrate 101 may form an insulation region around the substrate 100. The insulation substrate 101 may include, for example, at least one of silicon oxide, silicon nitride, silicon oxynitride, and silicon carbide, but example embodiments are not limited thereto.

According to some example embodiments, a lower surface of the insulation substrate 101 is illustrated only as being disposed on a plane common to a lower surface of the substrate 100, but example embodiments are not limited thereto. As another example, the lower surface of the insulation substrate 101 may be lower than the lower surface of the substrate 100.

According to some example embodiments, each of the plurality of insulation films 105 may include an insulation material. For example, the plurality of insulation films 105 may include at least one of silicon oxide, silicon nitride, and silicon oxynitride, but example embodiments are not limited thereto.

According to some example embodiments, the inter-layer insulation film 140 may be formed on the substrate 100 to cover the plurality of first electrodes 110 and the plurality of insulation films 105. The inter-layer insulation film 140 may include, for example, at least one of silicon oxide, silicon oxynitride, and a low-permittivity (low-k) material having permittivity lower than that of silicon oxide, but example embodiments are not limited thereto.

According to some example embodiments, the plurality of first electrodes 110, the second electrode 120, and the variable resistance device layer 130 may form memory cell of the cell structure CELL. The second electrode 120 and the variable resistance device layer 130 may be extended in the first direction D1, which crosses an upper surface of the substrate 100, to penetrate the plurality of first electrodes 110 and the plurality of insulation films 105.

According to some example embodiments, in a second direction D2 and a third direction D3 parallel to the upper surface of the substrate 100, the second electrode 120 may be staggered from another, and the variable resistance device layer 130 may be staggered from another. The second electrode 120 and the variable resistance device layer 130 which are arranged in a zigzag form may further improve integration density of the semiconductor device. In some example embodiments, a plurality of second electrodes 120 and variable resistance device layers 130 may be arranged in a honeycomb form. Since like features are described above with reference to FIGS. 1 through 3, descriptions for the plurality of first electrodes 110, the second electrode 120, and the variable resistance device layer 130 will be omitted.

According to some example embodiments, the cell wiring line 180 may be formed above the plurality of first electrodes 110 and the plurality of insulation films 105. The cell wiring line 180 may be extended in the third direction D3 to be connected to a plurality of second electrodes 120 arranged in the third direction D3. For example, a cell wiring contact 182 connected to an upper portion of each of the second electrodes 120 may be formed in the inter-layer insulation film 140. The cell wiring line 180 may be electrically connected to the second electrodes 120 through the cell wiring contact 182.

According to some example embodiments, the cell wiring line 180 may be formed on the inter-layer insulation film 140. The cell wiring line 180 may be formed in a first inter-wiring insulation film 190. The cell wiring line 180 may be electrically connected to through the cell wiring contact 182 and the gate contact 162. Through this, the cell wiring line 180 may be electrically connected to the plurality of first electrodes 110 and the second electrode 120. The number of layers, disposition, and the like of the cell wiring line 180, which are illustrated, are merely examples.

According to some example embodiments, the cell wiring line 180 may be connected to a peripheral circuit element PT through a contact plug 166. A peripheral circuit wiring structure 260 connected to the peripheral circuit element PT may be formed in a second inter-wiring insulation film 240. The contact plug 166 may be extended in the first direction D1 to connect the cell wiring line 180 and the peripheral circuit wiring structure 260. Through this, the cell wiring line 180 and/or the plurality of first electrodes 110 may be electrically connected to the peripheral circuit device PT.

According to some example embodiments, the gate contact 162 may be connected to the plurality of first electrodes 110. For example, the gate contact 162 may be extended in the first direction D1 in the inter-layer insulation film 140 to be connected to the plurality of first electrodes 110. In some example embodiments, the gate contact 162 may have a bent portion in the inter-layer insulation film 140.

According to some example embodiments, a source contact 164 may be connected to the substrate 100. For example, the source contact 164 may be extended in the first direction D1 in the inter-layer insulation film 140 to be connected to the substrate 100. In some example embodiments, the source contact 164 may have a bent portion in the inter-layer insulation film 140. The source contact 164 may electrically connect the substrate 100 and the cell wiring line 180.

According to some example embodiments, the contact plug 166 may penetrate the insulation substrate 101 to connect the cell wiring line 180 and the peripheral circuit wiring structure 260. The contact plug 166 may be electrically separated from the substrate 100.

According to some example embodiments, each of the gate contact 162, the source contact 164, and the contact plug 166 may be connected to the cell wiring line 180 on the inter-layer insulation film 140. The first inter-wiring insulation film 190 may be formed on an inter-layer insulation film 140. The cell wiring line 180 may be formed in the first inter-wiring insulation film 190. Each of the gate contact 162, the source contact 164, and the contact plug 166 may be connected to the cell wiring line 180 by a contact via 184.

According to some example embodiments, a peripheral circuit structure PERI may include a peripheral circuit substrate 200, the peripheral circuit element PT, and the peripheral circuit wiring structure 260.

According to some example embodiments, the peripheral circuit substrate 200 may be disposed below the substrate 100. According to some example embodiments, the peripheral circuit substrate 200 may include, for example, a semiconductor substrate such as a silicon substrate, a germanium substrate, or a silicon-germanium substrate. Alternatively, the peripheral circuit substrate 200 may include a silicon-on-insulator (SOI) substrate, a germanium-on-insulator (GOI) substrate, or the like.

According to some example embodiments, the peripheral circuit element PT may be formed on the peripheral circuit substrate 200. The peripheral circuit element PT may form a peripheral circuit that controls an operation of the semiconductor device. The peripheral circuit element PT may include, for example, a transistor, but example embodiments are not limited thereto. For example, the peripheral circuit element PT may include not only various active elements such as the transistor but also various passive elements such as a capacitor, a resistor, or an inductor.

According to some example embodiments, the cell structure CELL may be stacked on the peripheral circuit structure PERI. For example, the cell structure CELL may be stacked on the second inter-wiring insulation film 240.

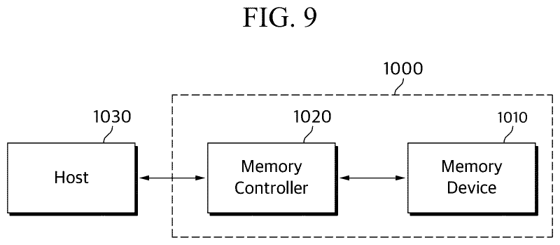

FIG. 9 is a schematic diagram of an electronic system including a semiconductor device according to some embodiments.

Referring to FIG. 9, a memory system 1000 may include a memory device 1010 for storing data and a memory controller 1020. The memory controller 1020 may read or write data from/into the memory device 1010 in response to read/write request of a host 1030. The memory controller 1020 may make an address mapping table for mapping an address provided from the host 1030 (e.g., a mobile device or a computer system) into a physical address of the memory device 1010.

The memory controller 1020 may be implemented with processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The memory device 1010 may include a plurality of memory cells. The memory device may include a semiconductor device according to example embodiments in FIGS. 1, 2, 3, or 8 of the present application.

While various example embodiments of the present disclosure have been described above in detail, but the scope of the present disclosure is not limited thereto. It will be apparent to those skilled in the art that various changes and modifications may be allowed within the range of the technical spirit of the present disclosure. In addition, the above-described example embodiments may be implemented without a portion of elements thereof, and each of the example embodiments may be implemented in combination with another.

What is claimed is:

1. A semiconductor device comprising:
a plurality of first electrodes stacked above a substrate in a first direction;
a second electrode penetrating the plurality of first electrodes; and
a variable resistance device layer surrounding the second electrode,
wherein a work function of a material in the plurality of first electrodes is smaller than a work function of a material in the second electrode.

2. The semiconductor device of claim 1, wherein the variable resistance device layer is a single film.

3. The semiconductor device of claim 1, wherein
an upper surface of the second electrode is higher above the substrate than an upper surface of the variable resistance device layer.

4. The semiconductor device of claim 1, wherein each of the plurality of first electrodes comprises a semiconductor material doped with an impurity.

5. The semiconductor device of claim 4, wherein each of the plurality of first electrodes comprises silicon (Si).

6. The semiconductor device of claim 1, wherein an inner side wall of the variable resistance device layer is in contact with the second electrode.

7. The semiconductor device of claim 1, wherein the second electrode has a pillar shape.

8. The semiconductor device of claim 1, wherein the variable resistance device layer extends in the first direction between the plurality of first electrodes and the second electrode.

9. The semiconductor device of claim 1, further comprising:
an insulation film between the plurality of first electrodes in the first direction.

10. The semiconductor device of claim 1, wherein an electric current flows in one direction in the variable resistance device layer between the second electrode and each of the plurality of first electrodes.

11. The semiconductor device of claim 1, wherein the second electrode extends in in the first direction and crosses the plurality of first electrodes.

12. A method of fabricating a semiconductor device, the method comprising:
alternately stacking a plurality of insulation films and a plurality of first electrodes in a first direction;
forming a hole penetrating the plurality of insulation films and the plurality of first electrodes in the first direction;
forming a variable resistance device layer on an inner side wall of the hole, and
forming a second electrode in the hole to fill the hole, the second electrode being on the variable resistance device layer.

13. The method of claim 12, wherein a work function of a material in the plurality of first electrodes is smaller than a work function of a material in the second electrode.

14. The method of claim 12, wherein the second electrode is formed to contact with an inner side wall of the variable resistance device layer.

15. The method of claim 12, wherein each of the plurality of first electrodes comprises a semiconductor material doped with an impurity.

16. The method of claim 12, wherein the variable resistance device layer is formed as a single film.

17. The method of claim 12, wherein the second electrode extends in the first direction and crosses the plurality of first electrodes.

18. The method of claim 12, wherein the variable resistance device layer extends in the first direction.

19. The method of claim 12, wherein the plurality of insulation films comprise silicon oxide.

20. A semiconductor device comprising:
a plurality of first electrodes stacked above a substrate in a first direction, the plurality of first electrodes comprising silicon doped with an impurity;
a second electrode penetrating the plurality of first electrodes and extending in the first direction; and
a single-film variable resistance device layer surrounding the second electrode and connected to the plurality of first electrodes,
wherein a work function of a material in the plurality of first electrodes is smaller than a work function of a material in the second electrode.
